(19) United States
(12) Patent Application Publication
(10) Pub. No.: US 2009/0160456 A1
(43) Pub. Date: Jun. 25, 2009

(54) DEVICE FOR INSPECTING SOLDERING SPOTS IN A STORAGE BATTERY

(75) Inventors: Kuen-Cheng Wang, Taichung City (TW); Tsair-Rong Chen, Changhua City (TW); Jeen-Sheen Row, Changhua City (TW)

Correspondence Address: LADAS & PARRY, 5670 WILSHIRE BOULEVARD, SUITE 2100, LOS ANGELES, CA, 90036-5679, US

(73) Assignees: Kuen-Cheng Wang, Taichung City (TW); Department of Electrical Engineering, National Chang-Hua University of Education, Changhua City (TW)

(21) Appl. No.: 11/960,492

(22) Filed: Dec. 19, 2007

(51) Int. Cl. G01R 31/04

(52) U.S. Cl. 324/537

(57) ABSTRACT

A device for inspecting a soldering spot in a storage battery includes a power supply unit and an inspecting unit. The power supply unit outputs a test power signal to be applied to the soldering spot. The inspecting unit includes first and second inspecting terminals, and a control module. The first and second inspecting terminals are adapted to be connected electrically to the soldering spot so as to detect response of the soldering spot to application of the test power signal by the power supply unit. The control module determines if a detected response of the soldering spot as detected through the first and second inspecting terminals falls within a predetermined range configured in the control module, generates an indication signal if the detected response falls outside the predetermined range, and generates an inspection result corresponding to the detected response.

### BACKGROUND OF THE INVENTION

1. Field of the Invention

The invention relates to a device for inspecting a storage battery, more particularly to a device for inspecting soldering spots in a storage battery.

2. Description of the Related Art

A storage battery generally includes a plurality of electrode plates, which are immersed in an electrolytic solution and which are interconnected sequentially in series. The series connections among the electrode plates are accomplished by soldering adjacent pairs of soldering lugs of the electrode plates of the storage battery. If the soldering spots are not firm, failure of the series connections is likely to occur. Moreover, in case there is air trapped in a soldering spot, breaking of the soldering spot is likely to occur when a large electric current passes therethrough, such as when a car engine is started.

Therefore, there is thus a need to find ways to determine the quality of soldering spots so as to ensure the quality of a storage battery product.

### SUMMARY OF THE INVENTION

Therefore, the object of the present invention is to provide a device for inspecting a soldering spot in a storage battery, which can provide inspection results for storage by an external processing device.

Accordingly, the device of the present invention is adapted for inspecting a soldering spot that interconnects electrically an adjacent pair of soldering lugs of a storage battery. The device comprises a power supply unit and an inspecting unit. The power supply unit outputs a test power signal to be applied to the soldering spot. The inspecting unit includes first and second inspecting terminals, and a control module. The first and second inspecting terminals are adapted to be connected electrically to the soldering spot so as to detect response of the soldering spot to application of the test power signal by the power supply unit. The control module determines if a detected response of the soldering spot as detected through the first and second inspecting terminals falls within a predetermined range configured in the control module, generates an indication signal if the detected response falls outside the predetermined range, and generates an inspection result corresponding to the detected response.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic sectional view of a conventional storage battery to be inspected by the device according to the present invention;

FIG. 2 is a schematic view of the preferred embodiment of a device for inspecting a soldering spot in a storage battery according to the present invention; and

FIG. 3 is a schematic block diagram of the preferred embodiment.

### DETAILED DESCRIPTION OF THE PREFERRED EMBODIMENT

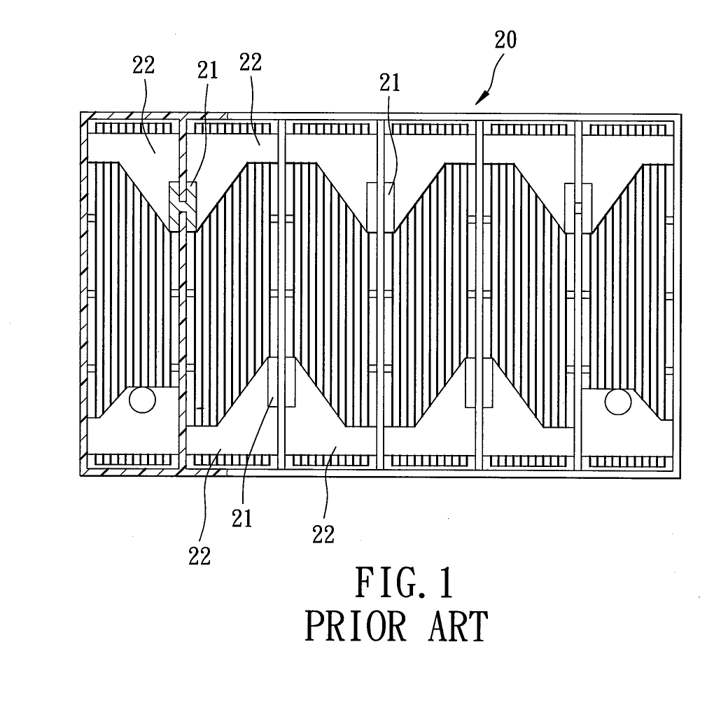

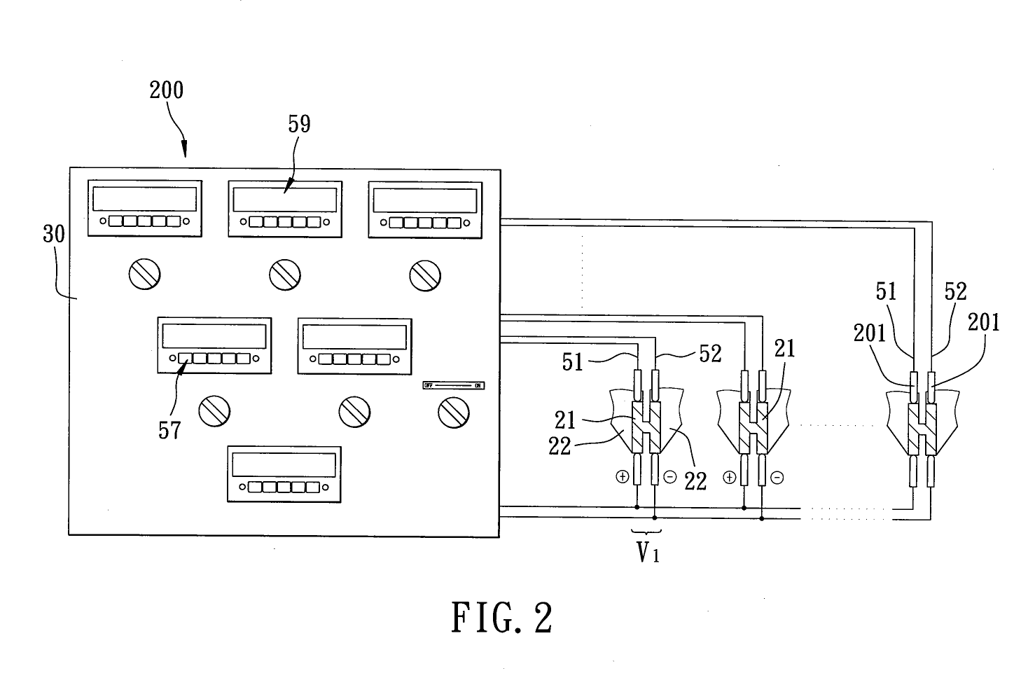

Referring to FIGS. 1 to 3, the preferred embodiment of a device 200 according to the present invention is adapted for inspecting soldering spots 21 that interconnect electrically adjacent pairs of soldering lugs 22 of a storage battery 20. The device 200 comprises a housing 30, a power supply unit 40, and an inspecting unit 50. In this embodiment, the device 200 is used to inspect five soldering spots 21 in the storage battery 20.

The power supply unit 40 is disposed in the housing 30 and is operable to output a test power signal (V₁) that is to be applied across opposite end portions of each of the soldering spots 21.

The inspecting unit 50 is disposed in the housing 30, and includes a plurality of first inspecting terminals 51, a plurality of second inspecting terminals 52, an input module 53 coupled to the first and second inspecting terminals 51, 52, an analog-to-digital converting module 54 coupled to the input module 53, a control module 55 coupled to the analog-to-digital converting module 54 and configured with a predetermined range, a transmission interface 56 coupled to the control module 55, an operating interface 57 coupled to the control module 55, a control interface 58 coupled to the control module 55, and an indication interface 59 coupled to the control module 55.

Each pair of the first and second inspecting terminals 51, 52 are to be coupled electrically and respectively to the opposite end portions of a corresponding one of the soldering spots 21. In practice, the first and second inspecting terminals 51, 52 and the power supply unit 40 are coupled to the soldering spots 21 with the use of contact probes 201.

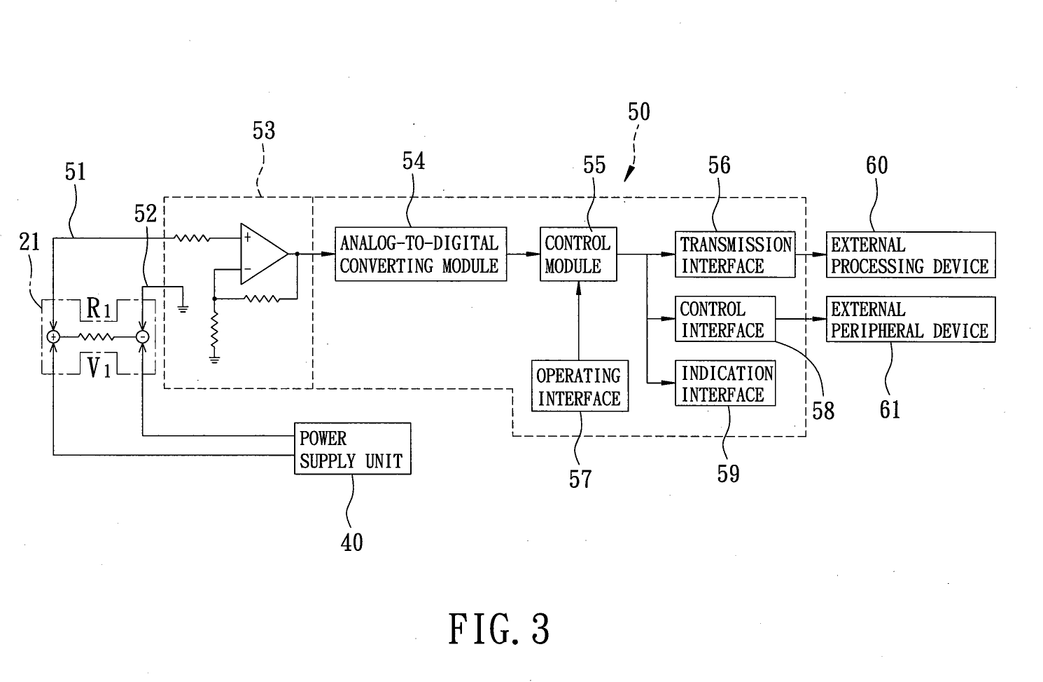

The input module 53 includes a buffer circuit built from an operational amplifier. FIG. 3 shows one buffer circuit to correspond with a pair of the first and second inspecting terminals 51, 52. In practice, there is a plurality of buffer circuits to correspond with the plurality of pairs of the first and second inspecting terminals 51, 52.

The control module 55 determines if a detected response of each of the soldering spots 21 as detected through the corresponding pair of the first and second inspecting terminals 51, 52 falls within the predetermined range configured in the control module 55, generates an indication signal if the detected response falls outside the predetermined range, and generates an inspection result corresponding to the detected response. In this embodiment, the predetermined range is a resistance range.

The transmission interface 56 permits supply of the inspection results to an external processing device 60, which is responsible for storing, analyzing and computing the same. The results of analysis and computations made by the external processing device 60 can be subsequently used to evaluate the quality of a batch of storage battery products.

The operating interface 57 permits configuring of the predetermined range, i.e., the resistance range, in the control module 55.

The control interface 58 permits supply of a control signal generated by the control module 55 to an external peripheral device 61 for controlling operation of the external peripheral device 61. As an example, the external peripheral device 61 can be one for controlling movements of the probes 201 and the storage battery 20 so as to achieve an automated inspection effect.

The indication interface 59 is for providing a visual indication of the inspection results, and permits output of the indication signal from the control module 55 therethrough.

When inspecting a storage battery 20, the test power signal (V₁) is applied to the soldering spots 21 and the first and second inspecting terminals 51, 52 are coupled to the soldering spots 21 in pairs with the use of the probes 201. Since each soldering spot 21 has a small resistance (R₁), the electric currents flowing through the soldering spots 21 as a result of application of the test power signal (V₁) can be converted by the input module 53 into corresponding voltages, which are subsequently converted by the analog-to-digital converting module 54 into digital signals that are provided to the control module 55. The control module 55 converts the digital signals into resistance values corresponding to the soldering spots 21. If the resistance value of one of the soldering spots 21 falls outside the predetermined range configured in the control module 55, the soldering spot 21 is determined to be a poor connection that needs to be re-soldered.

Since inspection of the soldering spots 21 is conducted by the inspecting unit 50 using electrical signals, the quality of the soldering spots 21 can be accurately determined. Furthermore, by outputting the inspection results through the transmission interface 56, the inspection results can be stored for future evaluation of the quality of a batch of storage battery products.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A device for inspecting a soldering spot in a storage battery, the soldering spot interconnecting electrically an adjacent pair of soldering lugs of the storage battery, said device comprising:
a power supply unit for outputting a test power signal to be applied to the soldering spot; and
an inspecting unit including
first and second inspecting terminals adapted to be connected electrically to the soldering spot so as to detect response of the soldering spot to application of the test power signal by said power supply unit, and
a control module for determining if a detected response of the soldering spot as detected through said first and second inspecting terminals falls within a predetermined range configured in said control module, for generating an indication signal if the detected response falls outside the predetermined range, and for generating an inspection result corresponding to the detected response.

2. The device as claimed in claim 1, wherein the predetermined range is a resistance range, and said inspecting unit further includes an input module coupled to said first and second inspecting terminals, and an analog-to-digital converting module coupled between said input module and said control module,
said control module obtaining the detected response through said input module and said analog-to-digital converting module, converting the detected response to a corresponding resistance value, and determining if the resistance value corresponding to the detected response falls within the resistance range.

3. The device as claimed in claim 1, wherein said inspecting unit further includes an indication interface coupled to said control module to permit output of the indication signal therethrough, and a transmission interface coupled to said control module to permit supply of the inspection result to an external processing device.

4. The device as claimed in claim 1, wherein said inspecting unit further includes an operating interface coupled to said control module to permit configuring of the predetermined range in said control module.

5. The device as claimed in claim 1, wherein said control module further generates a control signal, and said inspecting unit further includes a control interface to permit supply of the control signal to an external peripheral device for controlling operation of the external peripheral device.

6. The device as claimed in claim 1, further comprising a housing that houses said power supply unit and said inspecting unit.
